(19) United States
(12) Patent Application Publication
(10) Pub. No.: US 2025/0104982 A1
(43) Pub. Date: Mar. 27, 2025

(54) MONITORING AND CONTROL OF PLASMA-BASED PROCESSES

(71) Applicant: Lam Research Corporation, Fremont, CA (US)

(72) Inventors: Gordon Alex MacDonald, West Linn, OR (US); Ragesh Puthenkovilakam, Portland, OR (US); Todd Schroeder, Sherwood, OR (US); Chin-Jui Hsu, Portland, OR (US); Sagar Balagangadhara Udyavara, Beaverton, OR (US); Kapu Sirish Reddy, Portland, OR (US); Yukinori Sakiyama, West Linn, OR (US)

(21) Appl. No.: 18/291,202

(22) PCT Filed: Jul. 20, 2022
(86) PCT No.: PCT/US2022/037699

§ 371 Date: Jan. 22, 2024

Related U.S. Application Data
(60) Provisional application No. 63/224,824, filed on Jul. 22, 2021.

(51) Int. Cl. H01J 37/32

(52) U.S. Cl. CPC H01J 37/32926; H01J 37/32091; H01J 37/32963

(57) ABSTRACT

An apparatus comprises a vacuum chamber with a processing zone, an RF generator, a sensor, and a controller. The vacuum chamber is configured to receive process gas for a plasma-based process of a substrate. The RF generator provides an RF signal between a first electrode and a second electrode of the vacuum chamber to generate plasma for the plasma-based process. The sensor is configured to sense at least one signal characteristic of the RF signal. The controller is configured to retrieve during the plasma-based process, a plurality of signals from the sensor. The plurality of signals is indicative of the at least one signal characteristic of the RF signal at a corresponding plurality of time instances. The controller determines an endpoint for the plasma-based process based on the plurality of signals from the sensor. The controller terminates the plasma-based process based on the endpoint.

### CLAIM OF PRIORITY

This application claims the benefit of priority to U.S. Patent Application Ser. No. 63/224,824, filed on Jul. 22, 2021, which is incorporated by reference herein in its entirety.

### TECHNICAL FIELD

The subject matter disclosed herein generally relates to methods, systems, and machine-readable storage media for in-situ monitoring and control of plasma-based processes, such as capacitively coupled plasma (CCP) or inductively coupled plasma (ICP) substrate manufacturing.

### BACKGROUND

Semiconductor substrate processing systems are used to process semiconductor substrates by techniques including etching, physical vapor deposition (PVD), chemical vapor deposition (CVD), plasma-enhanced chemical vapor deposition (PECVD), atomic layer deposition (ALD), plasma-enhanced atomic layer deposition (PEALD), pulsed deposition layer (PDL), plasma-enhanced pulsed deposition layer (PEPDL), and resist removal. One type of semiconductor substrate processing apparatus is a plasma processing apparatus using CCP that includes a vacuum chamber containing electrodes. A radio frequency (RF) power is applied between the electrodes to excite a process gas into plasma for processing semiconductor substrates in the reaction chamber. Another type of semiconductor substrate processing apparatus is an ICP plasma processing apparatus.

In semiconductor substrate processing systems, tuning plasma-based processes such as deposition and etching is important for achieving substrate uniformity and consistency. Existing techniques for evaluating substrates in connection with process tuning are either time-consuming (e.g., critical dimension scanning electron microscope or CDSEM) or destructive (e.g., cross-section electron microscope or XSEM).

The background description provided herein is to generally present the context of the disclosure. It should be noted that the information described in this section is presented to provide the skilled artisan some context for the following disclosed subject matter and should not be considered as admitted prior art. More specifically, the work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods, systems, and computer programs are presented for in-situ monitoring and control of plasma-based processes. One general aspect of the disclosure is an apparatus comprising a vacuum chamber, a radio frequency (RF) generator, a sensor, and a controller. The vacuum chamber comprises a processing zone. The vacuum chamber is configured to receive process gas for a plasma-based process of a substrate. The RF generator is configured to provide an RF signal between a first electrode and a second electrode of the vacuum chamber to generate plasma for the plasma-based process. The plasma is generated within the processing zone using the process gas. The sensor is coupled to the RF generator. The sensor is configured to sense at least one signal characteristic of the RF signal. The controller is coupled to the sensor and is configured to retrieve, during the plasma-based process, a plurality of signals from the sensor. The plurality of signals is indicative of the at least one signal characteristic of the RF signal at a corresponding plurality of time instances. The controller can generate a plurality of derivative signals based on the plurality of signals. The controller can determine an endpoint for the plasma-based process based on the plurality of derivative signals. The controller can terminate the plasma-based process based on the endpoint (e.g., based on a time associated with the endpoint).

Another general aspect includes a method for processing a substrate using a plasma-based process. The method includes applying an RF signal between a first electrode and a second electrode of a vacuum chamber to generate plasma for the plasma-based process. The method further includes receiving during the plasma-based process, a plurality of sensor signals. The plurality of sensor signals is indicative of at least one signal characteristic of the RF signal at a corresponding plurality of time instances. The method further includes determining an endpoint for the plasma-based process based on the plurality of sensor signals. The method further includes terminating the plasma-based process based on the endpoint.

An additional general aspect includes a non-transitory machine-readable storage medium including instructions that, when executed by a machine, cause the machine to perform operations for processing a substrate. The operations include applying an RF signal between a first electrode and a second electrode of a vacuum chamber to generate plasma for a plasma-based process. The operations further include receiving during the plasma-based process, a plurality of sensor signals. The plurality of sensor signals can be indicative of at least one signal characteristic of the RF signal at a corresponding plurality of time instances. The operations further include generating a plurality of derivative signals based on the plurality of sensor signals. The operations further include determining an endpoint for the plasma-based process based on the plurality of derivative signals. The operations further include terminating the plasma-based process based on the endpoint.

### BRIEF DESCRIPTION OF THE DRAWINGS

Various ones of the appended drawings merely illustrate example embodiments of the present disclosure and cannot be considered as limiting its scope.

FIG. 1 illustrates a vacuum chamber, such as an etching chamber, for manufacturing substrates, according to some example embodiments.

FIG. 2 is a flowchart of a method of in-situ monitoring and control of plasma-based processes, according to some example embodiments.

FIG. 3 illustrates graphs of collected sensor data for RF signals over time in connection with multiple deposition processes, according to some example embodiments.

FIG. 4 illustrates different graphs of collected sensor data for RF signals over time in connection with multiple deposition processes with different process gas flow rates, according to some example embodiments.

FIG. 5 illustrates graphs of collected sensor data including impedance associated with an RF signal and graphs of a plurality of derivative signals generated based on the sensor data for in-situ control of a plasma-based process, according to some embodiments.

FIG. 6 illustrates a graph of collected sensor data including voltage associated with an RF signal used for a first plasma-based etch process, according to some embodiments.

FIG. 7 illustrates a graph of a plurality of derivative signals generated based on the sensor data from FIG. 8 for in-situ control of the first plasma-based process, according to some embodiments.

FIG. 8 illustrates a graph of collected sensor data including voltage associated with an RF signal used for a second plasma-based etch process, according to some embodiments.

FIG. 9 illustrates a graph of a plurality of derivative signals generated based on the sensor data from FIG. 8 for in-situ control of the second plasma-based process, according to some embodiments.

FIG. 10 illustrates a graph of collected sensor data including voltage associated with an RF signal used for a third plasma-based etch process, according to some embodiments.

FIG. 11 illustrates a graph of a plurality of derivative signals generated based on the sensor data from FIG. 10 for in-situ control of the third plasma-based process, according to some embodiments.

FIG. 12 illustrates a graph of collected sensor data including voltage associated with an RF signal used for a fourth plasma-based etch process, according to some embodiments.

FIG. 13 illustrates a graph of a plurality of derivative signals generated based on the sensor data from FIG. 12, according to some embodiments.

FIG. 14 illustrates a graph of collected sensor data including impedance associated with an RF signal and a graph of a plurality of derivative signals generated based on the sensor data for in-situ control of a multi-step plasma-based process, according to some embodiments.

FIG. 15 is a flowchart of a method for processing a substrate using a plasma-based process, according to some example embodiments.

FIG. 16 is a block diagram illustrating an example of a machine upon which one or more example method embodiments may be implemented, or by which one or more example embodiments may be controlled.

### DETAILED DESCRIPTION

Example methods, systems, and computer programs are directed to in-situ monitoring and control of plasma-based processes performed in substrate manufacturing equipment. Examples merely typify possible variations. Unless explicitly stated otherwise, components and functions are optional and may be combined or subdivided, and operations may vary in sequence or be combined or subdivided. In the following description, for purposes of explanation, numerous specific details are set forth to provide a thorough understanding of example embodiments. It will be evident to one skilled in the art, however, that the present subject matter may be practiced without these specific details.

As used herein, the term “in-situ monitoring and control” indicates that the monitoring and control functions can be performed during a plasma-based process performed in a vacuum chamber of substrate manufacturing equipment. The term “plasma-based process” can comprise a deposition process, an etch process, or a multi-step process (e.g., a deposition process followed by an etch process).

Conventional techniques for configuring and tuning plasma-based processes performed in a vacuum chamber can include non-destructive approaches associated with the non-destructive analysis of the substrate. The conventional techniques can also include destructive approaches associated with the destructive analysis of the substrate. Example non-destructive approaches include using a critical dimension scanning electron microscope (CDSEM) to analyze a substrate after processing. Destructive approaches include using a cross-section electron microscope (XSEM) or scanning tunneling electron microscope (STEM) to analyze a substrate after processing. The conventional techniques are associated with the following drawbacks. CDSEM is time-consuming and may only be applied to a limited subset of substrates (due to the time-consuming nature of the measurement). CDSEM may only indicate if a plasma-based process (e.g., a deposition process or an etch process) has been completed. CDSEM does not indicate over-deposition or over-etch time. CDSEM provides uniformity information for partial fills or etches. However, CDSEM does not provide any uniformity information for completed fills or etches. XSEM is time-consuming and destructive. Additionally, XSEM may only be applied to a limited subset of substrates due to both slow turn-time and its destructive nature.

Techniques discussed herein can use a sensor (e.g., a Voltage-Current sensor) to measure at least one signal characteristic of RF signals provided in a vacuum chamber to generate the plasma for a plasma-based process. For example, the sensor may be coupled to the RF generator that generates the RF signals to measure voltage (V), current (I), phase, delivered power, and impedance. A plurality of signals from the sensor may be used for a non-destructive, in-line approach to determine when a structured top surface of a substrate (e.g., a substrate area with 3D NAND memory holes) has been filled (or plugged) during a deposition process based on the plurality of signals from the sensor. The plurality of signals from the sensor may also be used to determine when a planar top surface of a substrate is cleared during an etch process. This approach offers advantages both for process tuning and in-line process monitoring over slower approaches (e.g., CDSEM) and destructive approaches (e.g., XSEM, STEM). More specifically, the disclosed techniques may be used in-situ, on each substrate that is being processed, and without product loss or metrology delays. In some aspects, the plurality of signals from the sensor is used for generating a plurality of derivative signals. The plurality of derivative signals may be used for process optimization (e.g., during a plasma-based process development stage) including timing adjustment of different sub-processes of a plasma-based process. The plurality of derivative signals may also be used in in-situ monitoring and control (e.g., during a plasma-based process) to determine an endpoint for the plasma-based process. In some aspects, the plurality of derivative signals may also be used to estimate substrate uniformity and adjust process characteristics (e.g., process gas flow rate) based on estimated substrate uniformity. In other aspects, process optimization including timing adjustment of different sub-processes of the plasma-based process may be performed using raw sensor data (e.g., the plurality of signals from the sensor).

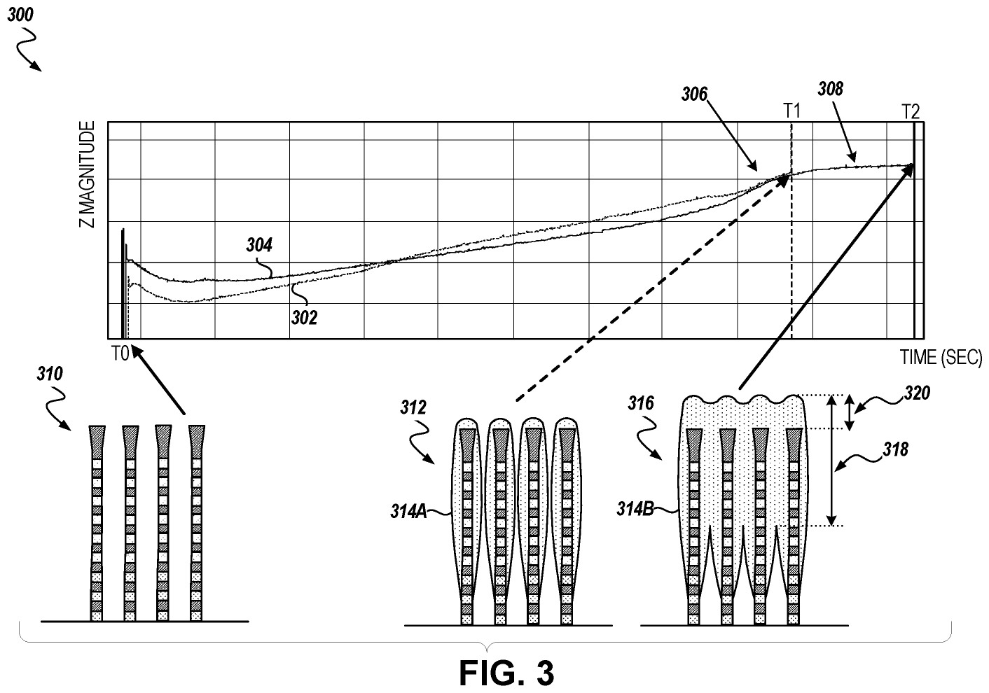

Some beneficial aspects of the disclosed techniques include substrate non-destructiveness as well as using sensor data that may be collected (or is already collected) at most vacuum chamber sites for every substrate processing run. Other beneficial aspects of the disclosed techniques are using readily available sensor data for a determination of a plasma-based process endpoint as well as monitoring the uniformity of plug closure rates across a substrate. As used herein, the term “endpoint” or “process endpoint” indicates a time when a plasma-based process is terminated (e.g., via interrupting a process gas flow and extinguishing the plasma used for the process). As used herein, the term “plug” indicates a formation filling a structured top surface of a substrate during a deposition process. In some aspects, a plug is generated from carbon depositions on the structured top surface of a substrate and may be referred to as a “carbon plug”. An example plug is illustrated in FIG. 3.

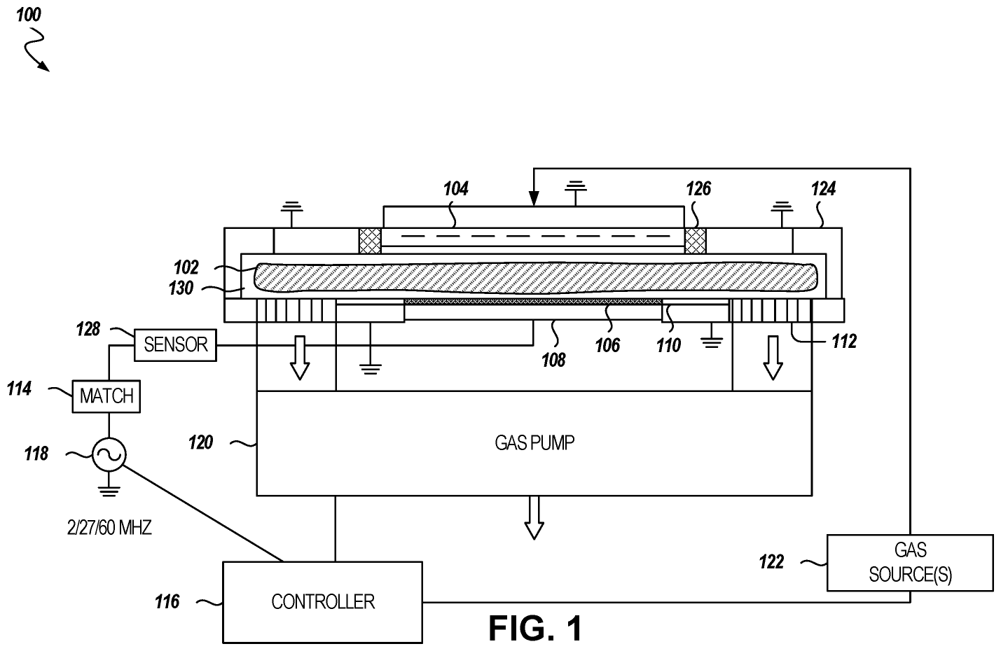

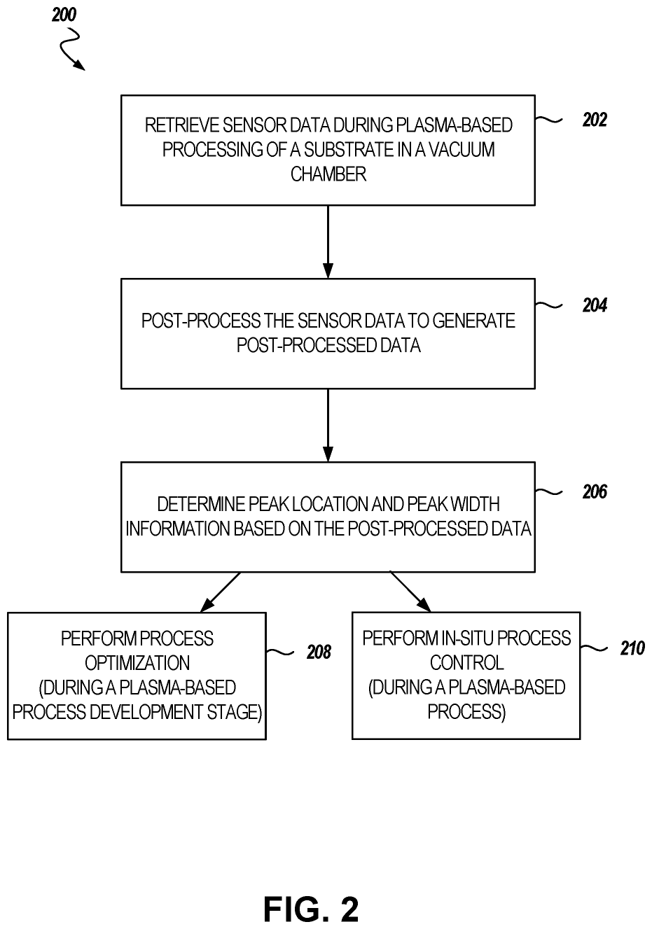

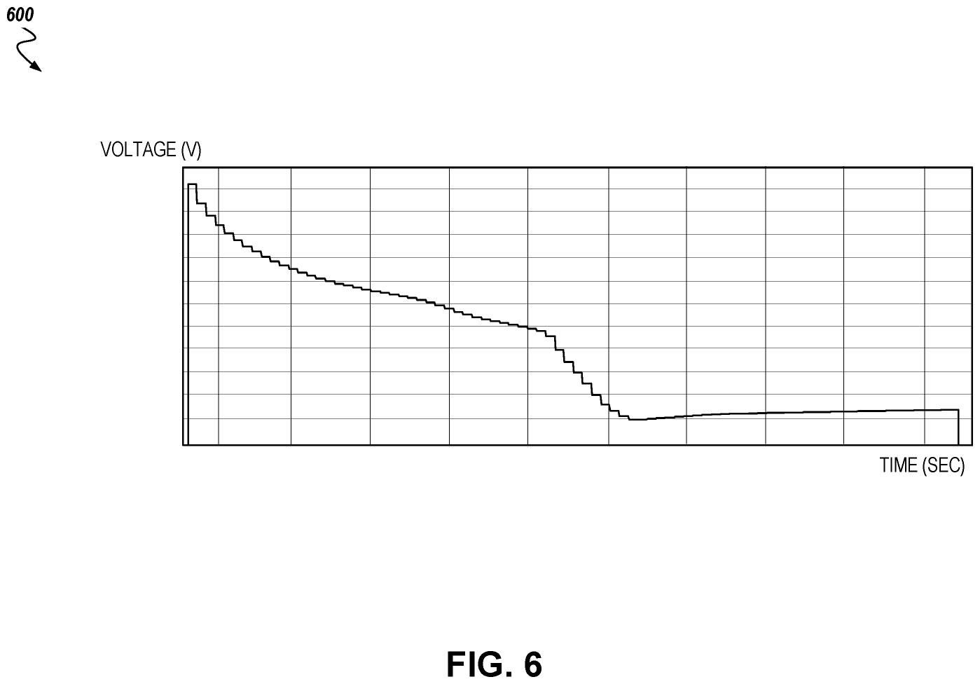

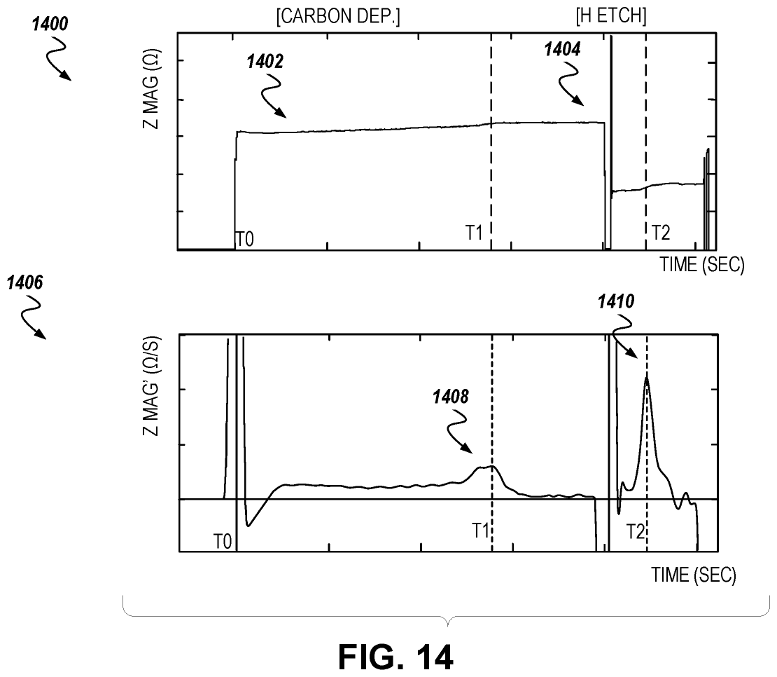

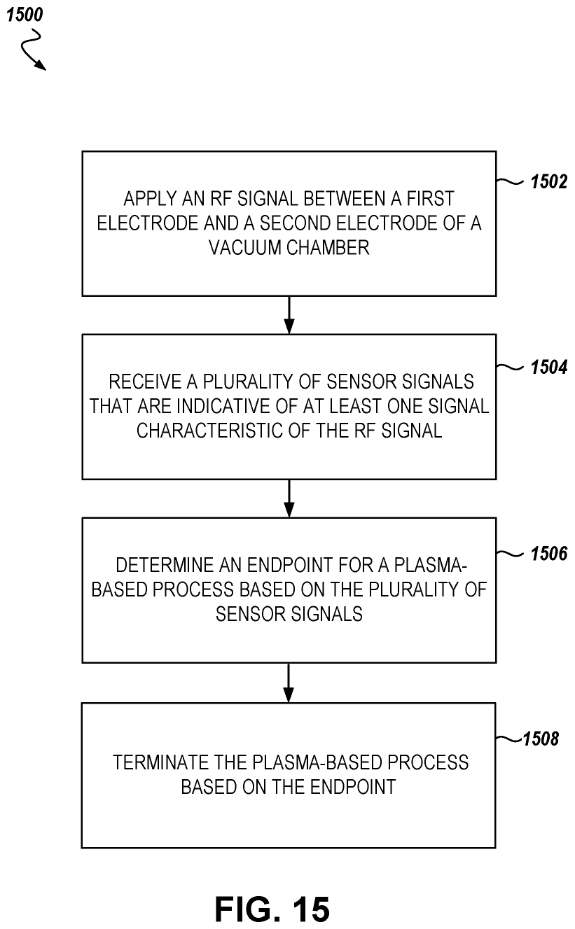

A general description of a vacuum chamber using the disclosed sensor in connection with in-situ monitoring and control of plasma-based processes is provided in connection with FIG. 1. Example flow diagrams of using the disclosed techniques are provided in FIG. 2 and FIG. 15. Example uses of the disclosed techniques for a deposition process are discussed in connection with FIG. 3-FIG. 5. Example uses of the disclosed techniques for an etch process are discussed in connection with FIG. 6-FIG. 13. Example uses of the disclosed techniques for a multi-step process (e.g., a deposition process followed by an etch process) are discussed in connection with FIG. 14.

FIG. 1 illustrates a vacuum chamber 100 (e.g., an etching chamber) for manufacturing substrates, according to one embodiment. Exciting an electric field between two electrodes is one of the methods to obtain radio frequency (RF) gas discharge in a vacuum chamber. When an oscillating voltage is applied between the electrodes, the discharge obtained is referred to as a CCP discharge.

Plasma 102 may be created within a processing zone 130 of the vacuum chamber 100 utilizing one or more process gases to obtain a wide variety of chemically reactive by-products created by the dissociation of the various molecules caused by electron-neutral collisions. The chemical aspect of etching involves the reaction of the neutral gas molecules and their dissociated by-products with the molecules of the to-be-etched surface and producing volatile molecules, which may be pumped away. When a plasma is created, the positive ions are accelerated from the plasma across a space-charge sheath separating the plasma from chamber walls to strike the substrate surface with enough energy to remove material from the substrate surface. The process of using highly energetic and chemically reactive ions to selectively and anisotropically remove materials from a substrate surface is called reactive ion etch (RIE). In some aspects, the vacuum chamber 100 may be used in connection with PECVD or PEALD deposition processes.

A controller 116 manages the operation of the vacuum chamber 100 by controlling the different elements in the chamber, such as RF generator 118, gas sources 122, and gas pump 120. In one embodiment, fluorocarbon gases, such as CF₄ and C₄F₈, are used in a dielectric etch process for their anisotropic and selective etching capabilities, but the principles described herein may be applied to other plasma-creating gases. The fluorocarbon gases are readily dissociated into chemically reactive by-products that include smaller molecular and atomic radicals. These chemically reactive by-products etch away the dielectric material.

The vacuum chamber 100 illustrates a processing chamber with multiple electrodes, such as an upper (or top) electrode 104 and a lower (or bottom) electrode 108. The upper electrode 104 may be grounded or coupled to an RF generator (not shown), and the lower electrode 108 is coupled to the RF generator 118 via a matching network 114. The RF generator 118 provides an RF signal between the upper electrode 104 and the lower electrode 108 to generate RF power in one or multiple (e.g., two or three) different RF frequencies. According to the desired configuration of the vacuum chamber 100 for a particular operation, at least one of the multiple RF frequencies may be turned ON or OFF. In the embodiment shown in FIG. 1, the RF generator 118 is configured to provide at least three different frequencies, e.g., 400 kHz, 2 MHZ, 27 MHz, and 60 MHz, but other frequencies are also possible.

The vacuum chamber 100 includes a gas showerhead on the top electrode 104 to input process gas into the vacuum chamber 100 provided by the gas source(s) 122, and a perforated confinement ring 112 that allows the gas to be pumped out of the vacuum chamber 100 by gas pump 120. In some example embodiments, the gas pump 120 is a turbomolecular pump, but other types of gas pumps may be utilized.

When substrate 106 is present in the vacuum chamber 100, silicon focus ring 110 is situated next to substrate 106 such that there is a uniform RF field at the bottom surface of the plasma 102 for uniform etching (or deposition) on the surface of the substrate 106. The embodiment of FIG. 1 shows a triode reactor configuration where the top electrode 104 is surrounded by a symmetric RF ground electrode 124. Insulator 126 is a dielectric that isolates the ground electrode 124 from the top electrode 104. Other implementations of the vacuum chamber 100, including ICP-based implementations, are also possible without changing the scope of the disclosed embodiments.

As used herein, the term “substrate” indicates a support material upon which, or within which, elements of a semiconductor device are fabricated or attached. A substrate (e.g., substrate 106) may include, for example, wafers (e.g., having a diameter of 100 mm, 150 mm, 200 mm, 300 mm, 450 mm, or larger) composed of, for example, elemental-semiconductor materials (e.g., silicon (Si) or germanium (Ge)) or compound-semiconductor materials (e.g., silicon germanium (SiGe) or gallium arsenide (GaAs)). Additionally, other substrates include, for example, dielectric materials such as quartz or sapphire (onto which semiconductor materials may be applied). Example substrates include blanket substrates and patterned substrates. A blanket substrate is a substrate that includes a low-surface (or planar) top surface. A patterned substrate is a substrate that includes a high-surface (or structured) top surface. A structured top surface of a substrate may include different high-surface-area structures such as 3D NAND memory holes or other structures.

Each frequency generated by the RF generator 118 may be selected for a specific purpose in the substrate manufacturing process. In the example of FIG. 1, with RF powers provided at 400 kHz, 2 MHZ, 27 MHz, and 60 MHz, the 400 kHz or 2 MHz RF power provides ion energy control, and the 27 MHz and 60 MHz powers provide control of the plasma density and the dissociation patterns of the chemistry. This configuration, where each RF power may be turned ON or OFF, enables certain processes that use ultra-low ion energy on the substrates, and certain processes (e.g., soft etch for low-k materials) where the ion energy has to be low (e.g., under 700 or 200 eV).

In another embodiment, a 60 MHz RF power is used on the upper electrode 104 to get ultra-low energies and very high density. This configuration allows chamber cleaning with high-density plasma when substrate 106 is not in the vacuum chamber 100 while minimizing sputtering on the electrostatic chuck (ESC) surface. The ESC surface is exposed when substrate 106 is not present, and any ion energy on the surface should be avoided, which is why the bottom 2 MHz and 27 MHz power supplies may be off during cleaning.

In an example embodiment, the vacuum chamber 100 further includes a sensor 128 which may be placed between the matching network 114 of the RF generator 118 and the lower electrode 108. The sensor 128 may include a voltage-current (or V-I) sensor configured to generate a plurality of signals (e.g., sensed data) that are indicative of at least one signal characteristic of RF signals generated by the RF generator 118 at a corresponding plurality of time instances. For example, the V-I sensor may generate a plurality of signals that are indicative of one or more of the following signal characteristics of RF signals: voltage, current, phase, delivered power, and impedance. In some aspects, the plurality of signals generated by the sensor 128 at the corresponding plurality of time instances may be stored (e.g., in the on-chip memory of controller 116 or the sensor 128) and later retrieved (e.g., by the controller 116) for subsequent processing. In other aspects, the plurality of signals generated by the sensor 128 at the corresponding plurality of time instances may be automatically communicated to the controller 116 as they are generated. Example

FIG. 2 is a flowchart of a method 200 of in-situ monitoring and control of plasma-based processes, according to some example embodiments. Referring to FIG. 2, method 200 may include operations 202, 204, 206, 208, and 210. Method 200 may be performed by controller 116 using data from sensor 128 illustrated in FIG. 1.

At operation 202, sensor data is retrieved during plasma-based processing of a substrate in a vacuum chamber. For example and in FIG. 1, sensor 128 generates a plurality of signals that are indicative of at least one signal characteristic of the RF signal generated by the RF generator 118. Sensor 128 generates the plurality of signals at a corresponding plurality of time instances. For example, sensor 128 may be configured to periodically (e.g., every second) sense the at least one signal characteristic of the RF signal (e.g., current, voltage, phase, power, or impedance). Controller 116 retrieves the sensor data (e.g., the plurality of signals) from sensor 128.

At operation 204, the sensor data is post-processed to generate post-processed data. For example, controller 116 may generate a plurality of derivative signals based on the plurality of signals from the sensor 128. In some embodiments, the plurality of signals from the sensor includes a plurality of impedances of the RF signal detected at the corresponding plurality of time instances. Controller 116 may then generate the plurality of derivative signals as derivatives of the corresponding plurality of impedances.

At operation 206, peak location and peak width information is determined based on the post-processed data. The determined peak location and peak width information may be used at operation 208 or operation 210. At operation 208, process optimization may be performed during a plasma-based process development stage using the information from operation 206. At operation 210, in-situ process control may be performed during a plasma-based process.

In some embodiments, the process optimization performed during the plasma-based process development stage may include monitoring for sufficient deposition (or etch) for a substrate process condition before destructive analysis is performed. The process optimization performed during the plasma-based process development stage may also include the determination of relative non-uniformity (e.g., measured as NU %) minimization before destructive analysis. Example non-uniformity minimization includes peak width minimization with heater ratio.

In other embodiments, the in-situ process control performed during the plasma-based process includes continuous statistical process control (SPC) data collection and monitoring. For example, with deposition processes (e.g., carbon plug fill deposition processes), monitoring both the derivative peak location for impedance versus time and the peak width of that peak could be used as a process control metric to prevent scaped product substrates that would result from the non-ideal performance of the carbon plug fill tool itself or due to a change in the incoming structure due to upstream processes. In the latter case, retuning the uniformity of the carbon process to better match the incoming structure's uniformity profile. For some deposition and etch processes, the disclosed techniques may be applied in-situ to determine the endpoint of a deposition or etch, minimizing the need for process retuning as a result of tool drift or changes to the incoming structure.

In some embodiments, the derivative signals of the impedances of the RF signal used during a carbon deposition process of a structured top surface substrate produce a peak that corresponds with the closing of a carbon plug in a 3D-NAND memory hole carbon deposition process. The formed peak may correspond to a positive peak derivative signal of the plurality of derivative signals generated by the controller using the sensor data. As used herein, the term “positive peak derivative signal” indicates a maximum positive derivative signal of the plurality of derivative signals. As used herein, the term “negative peak derivative signal” indicates a minimum negative derivative signal of the plurality of derivative signals.

In some aspects, the peak location may be indicative of the time it takes to form the carbon plug on the structures of the structured top surface substrate. The peak width may be used as an indicator of the substrate uniformity and the uniformity of the carbon plug closing times across the substrate wafer respectively. FIG. 3-FIG. 5 provide further illustration of using the disclosed techniques to perform in-situ determination of a deposition process endpoint.

A similar peak (e.g., a negative peak derivative signal) may be observed in connection with the etching processes of both blanket and patterned substrates. FIG. 6-FIG. 13 provide further illustration of using the disclosed techniques to perform in-situ determination of an etch process endpoint. FIG. 14 provides further illustration of using the disclosed techniques to perform in-situ determination of a deposition process endpoint followed by an etch process endpoint (e.g., in connection with a multi-step process that includes a deposition process followed by an etch process).

FIG. 3 illustrates a diagram 300 of graphs of collected sensor data for RF signals over time in connection with multiple deposition processes, according to some example embodiments. Referring to FIG. 3, graphs 302 and 304 illustrate a plurality of signals representing the inductance of the RF signals used in a first and a second deposition process respectively. More specifically, graph 302 represents the inductance magnitude over time for the first deposition process. Graph 304 represents the inductance magnitude over time for the second deposition process.

In some aspects, the substrate being processed may be a patterned substrate that includes a structured top surface 310 which has to be filled with a plug (e.g., a carbon plug) during the deposition process. In operation, both the first and second deposition processes start at time TO. In some aspects, time TO indicates the time when the RF generator provides the RF signal between a first electrode (e.g., the upper electrode) and a second electrode (e.g., the lower electrode) of the vacuum chamber to generate plasma using the process gas within the processing zone of the chamber.

The first deposition process represented by graph 302 terminates at time T1 when a curve (also referred to as “knee”) 306 has formed in graph 302. At time T1, the structured top surface 312 of the substrate is partially filled (or underfilled) with a partial plug 314A. The second deposition process represented by graph 304 continues further and terminates at time T2. By delaying the endpoint of the second deposition process by time duration (T2−T1), the structured top surface 316 is filled at endpoint T2. As illustrated in FIG. 3, the structured top surface 316 is filled by plug 314B characterized by plug depth 318 and plug overburden 320. As used herein, the term “plug depth” indicates the depth a plug reaches within a structured top surface. As used herein, the term “plug overburden” indicates the depth of a portion of the plug that extends above the structured top surface of a substrate. In an example embodiment, the plug depth 318 is equal to the height of the structured top surface 310.

As illustrated in FIG. 3, the slope 308 after the knee 306 and until the endpoint T2 is approaching 0. Consequently, a graph of derivative signals corresponding to the impedance values of graph 304 would result in a peak (e.g., a positive peak derivative signal) around time T1. The positive peak derivative signal would indicate the approximate time when the plug is starting to close (e.g., as illustrated by the partially filled structured top surface 312). The time instance (e.g., T1) associated with the positive peak derivative signal may be delayed by a predetermined threshold time duration (e.g., a time duration equal to the difference of (T2−T1)) to determine the second deposition process endpoint (e.g., time T2). By adding the predetermined threshold time duration, the second deposition process would end with a filled structured top surface 316 (instead of the partially filled structured top surface 312 if the second deposition process ended at time T1).

In some embodiments, the overburden depth 320 (or the plug depth 318) may be inspected in one or more prior deposition processes to determine the threshold time duration to add after a time instance associated with the positive peak derivative signal.

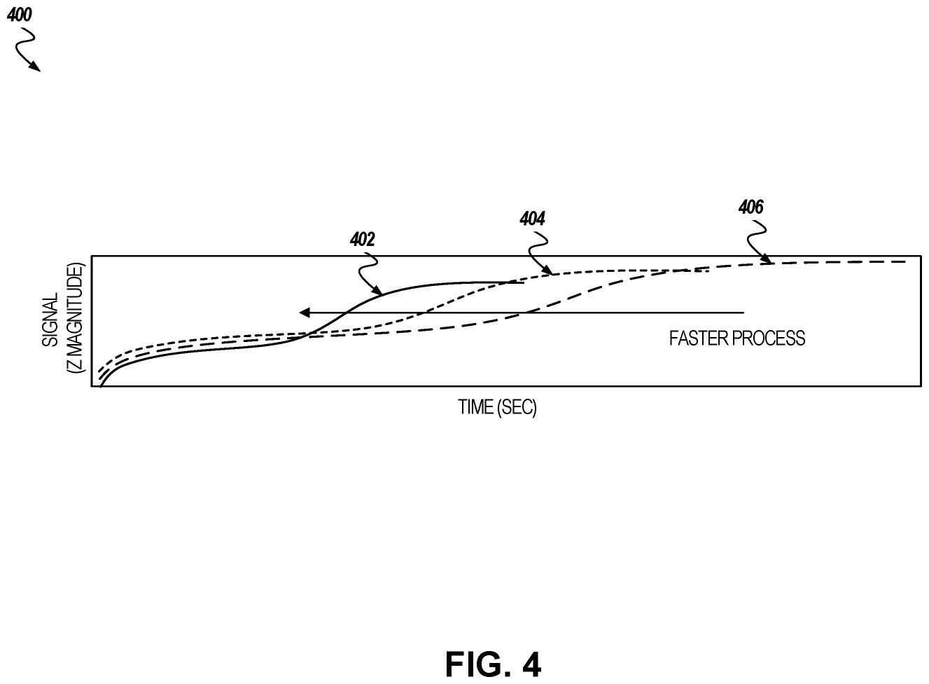

FIG. 4 illustrates a diagram 400 of different graphs of collected sensor data for RF signals over time in connection with multiple deposition processes with different process gas flow rates, according to some example embodiments. Referring to FIG. 4, graphs 402, 404, and 406 illustrate a plurality of signals representing the impedance of the RF signals used in three deposition processes with different process gas flow rates. For example, the deposition process represented by graph 406 uses the lowest process gas flow rate as the “knee” in graph 406 (which indicates the plug is starting to close) is at the latest time in comparison to the “knees” in graphs 402 and 404 associated with the remaining deposition processes. Similarly, the deposition process represented by graph 402 uses the highest process gas flow rate as the “knee” in graph 402 (which indicates the plug is starting to close) is at the earliest time in comparison to the “knees” in graphs 404 and 406. In this regard, the deposition process associated with graph 402 is also referred to as the “fastest” deposition process in comparison to the other deposition processes.

In some embodiments, sensor data (e.g., impedance data) associated with the RF signals used in multiple plasma-based processes may be analyzed to determine the time instances when the plug is starting to close (e.g., the “knee” locations in the graphs in FIG. 4) under different process gas flow rates.

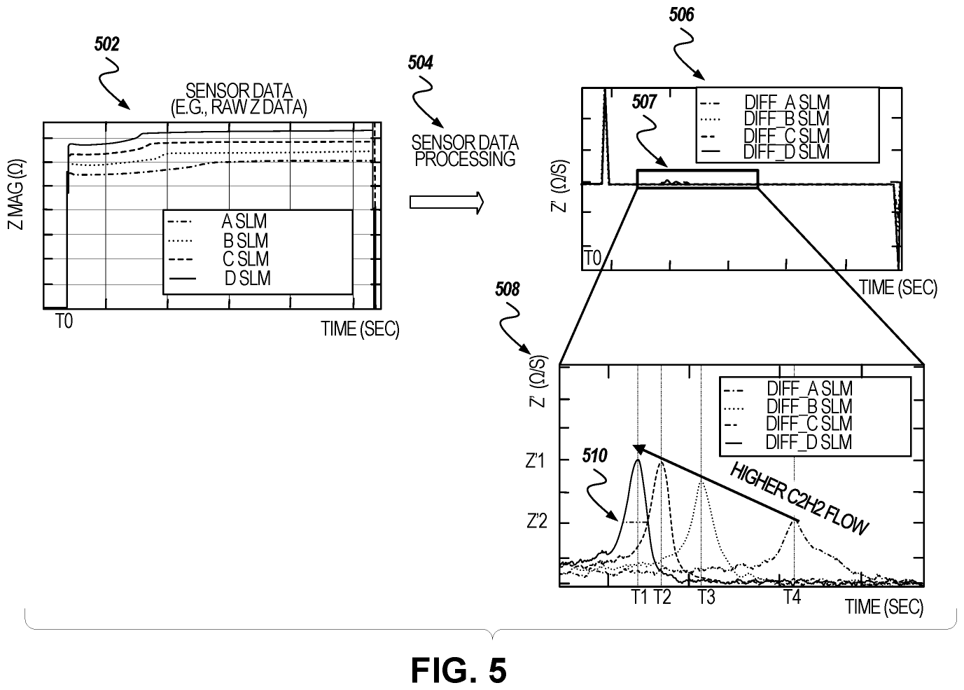

FIG. 5 illustrates graphs 502 of collected sensor data (also referred to as raw sensor data) including impedance associated with an RF signal, and graphs 506 of a plurality of derivative signals generated based on the sensor data for in-situ control of a plasma-based process, according to some embodiments.

Referring to FIG. 5, graphs 502 include impedance sensor data measured by sensor 128 over time in connection with deposition processes associated with different process gas flow rates ranging (e.g., flow rates ranging from A standard liter per minute (SLM) to D SLM, with A<D). The impedance sensor data is retrieved by the controller 116 (or otherwise automatically received by the controller 116) as a plurality of signals from the sensor 128. At operation 504, controller 116 performs sensor data processing to generate a plurality of derivative signals based on the retrieved plurality of signals (e.g., based on the impedance sensor data reflected by graphs 502). The plurality of derivative signals over time is reflected in graphs 506. In some aspects, controller 116 may determine an endpoint for each of the deposition processes based on the plurality of derivative signals. The corresponding deposition processes may be terminated based on the determined endpoints.

As illustrated in FIG. 5, the different deposition processes may start at time TO (e.g., when plasma is generated within the processing zone of the vacuum chamber), which is reflected as a peak in graphs 506. Portion 507 of the graphs 506 is magnified and illustrated as separate graphs 508 in FIG. 5. As the deposition processes continue, each of the processes reaches a time instance when the plug is starting to close, resulting in a positive peak derivative signal noted as a peak in graphs 508. More specifically, deposition processes with process gas flow rates of A SLM, B SLM, C SLM, and D SLM are associated with positive peak derivative signals at time instances T4, T3, T2, and T1 respectively.

In some embodiments, controller 116 detects these positive peak derivative signals after generating the plurality of derivative signals for a corresponding plurality of time instances for a deposition process. The positive peak derivative signals may correspond to a time instance of the plurality of time instances when a structured top surface of the substrate is beginning to close (or is filled) with a carbon plug during the deposition process. Controller 116 may determine the endpoint for the deposition process based on the time instance of the plurality of time instances. In some aspects, the endpoint for the deposition process is the time instance of the plurality of time instances delayed by a predetermined threshold time duration. For example, for the fastest deposition process (with a process gas flow rate of D SLM), the positive peak derivative signal is detected at time T1. Controller 116 may then determine the endpoint for the fastest deposition process by delaying (or extending) time T1 by a predetermined threshold time duration. In some embodiments, the predetermined threshold time duration corresponds to a predetermined depth of the carbon plug.

In an example embodiment, controller 116 may be further configured to determine a peak width associated with the peak derivative signal. In some aspects, peak width may be the width of the peak measured at half the derivative value. For example and about FIG. 5, the positive peak derivative signal for the fastest deposition process is at time T1 with a derivative value of the peak at approximately about Z′1 Ohm/s. The peak width 510 may be measured as the width of the peak at approximately about Z′2 Ohm/s (which may be half of Z′1).

In some embodiments, the peak width associated with the peak derivative signal may be indicative of substrate non-uniformity during the deposition process. In this regard, controller 116 may determine a non-uniformity estimate for the substrate at the time instance (e.g., T1) of the plurality of time instances based on the peak width (e.g., peak width 510). Controller 116 may further adjust the flow rate of the process gas during the plasma-based process based on the non-uniformity estimate.

In some embodiments, controller 116 may determine an endpoint for each of the deposition processes based on the raw sensor data instead of the plurality of derivative signals. More specifically, controller 116 may determine an endpoint for each of the deposition processes based on the raw sensor data being above a certain threshold.

FIG. 6 illustrates graph 600 of collected sensor data including voltage associated with an RF signal used for a first plasma-based etch process, according to some embodiments. More specifically, graph 600 is associated with a first plasma-based etch process which may be a carbon dioxide (CO₂) etch performed on a carbon substrate in a vacuum chamber, with a presence of carbon inside the chamber.

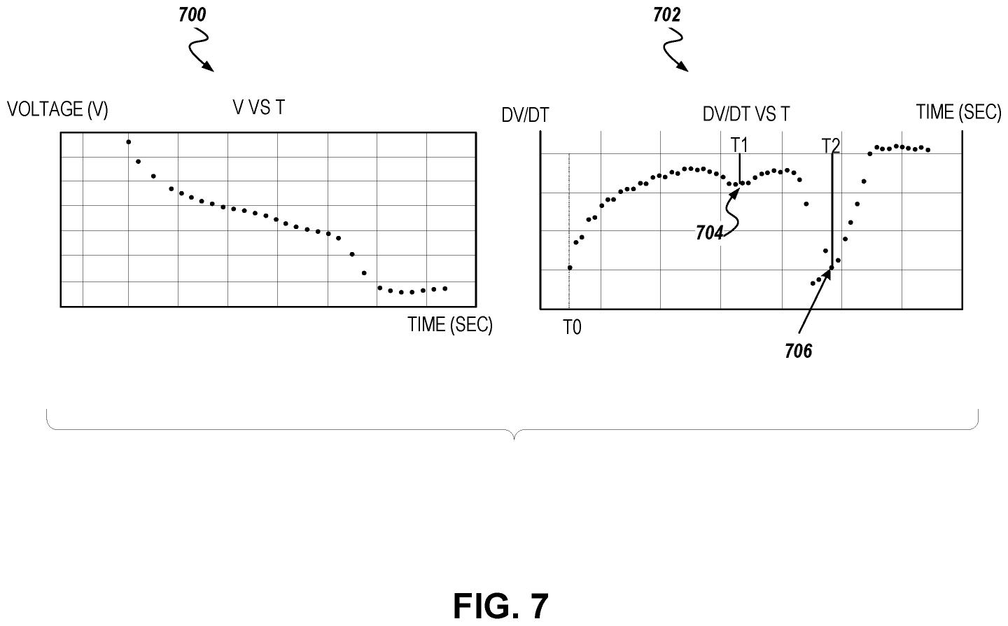

FIG. 7 illustrates graph 700 of selected sensor data from graph 600 corresponding to a plurality of time instances. FIG. 7 also illustrates graph 702 of a plurality of derivative signals generated based on the sensor data from FIG. 6 for in-situ control of the first plasma-based process, according to some embodiments. As illustrated in FIG. 7, the generated plurality of derivative signals in connection with an etch process may include one or more negative peak derivative signals, such as negative peak derivative signals 704 and 706 (seen as dips in graph 702). The first negative peak derivative signal 704 is at time T1, which is after time TO when the plasma for the etch process is initiated. The second negative peak derivative signal 706 is at time T2, which is after times TO and T1.

In some embodiments, the first negative peak derivative signal 704 may be detected by controller 116 as a derivative signal that corresponds to a first time instance of the plurality of time instances when the vacuum chamber is cleared of the presence of carbon. The second negative peak derivative signal 706 may be detected by controller 116 as a derivative signal that corresponds to a second time instance of the plurality of time instances when the carbon substrate (e.g., a planar top surface of the substrate) is cleared as a result of the etch process. In another embodiment, controller 116 may determine the endpoint for the etch process based on the second time instance of the plurality of time instances. In some aspects, the endpoint for the etch process may be the second time instance of the plurality of time instances delayed by a predetermined threshold time duration.

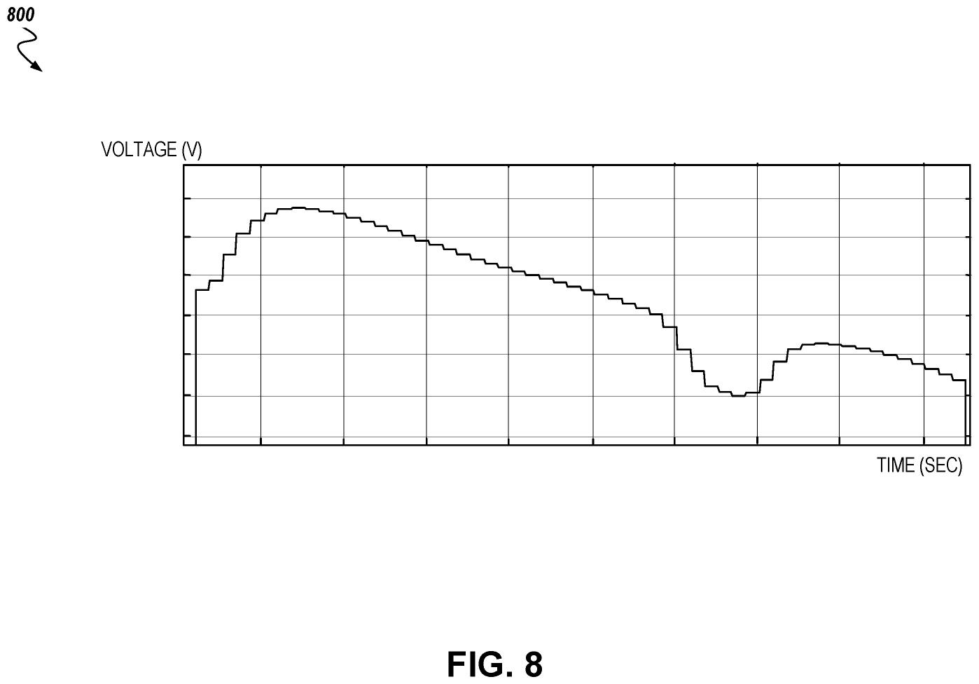

FIG. 8 illustrates graph 800 of collected sensor data including voltage associated with an RF signal used for a second plasma-based etch process, according to some embodiments. More specifically, graph 800 is associated with a second plasma-based etch process which may be a CO₂ etch performed on a carbon substrate in a clean vacuum chamber (without the presence of carbon inside the chamber).

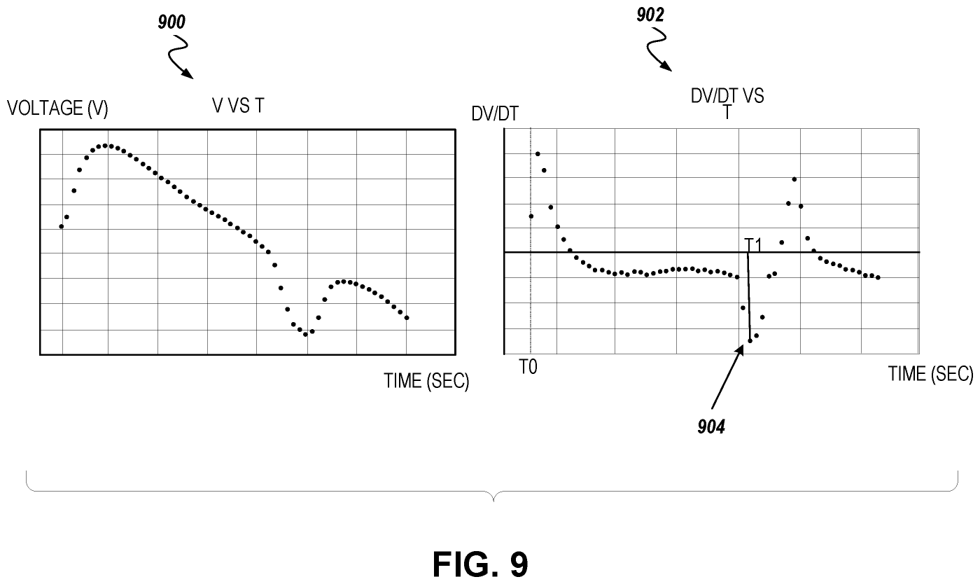

FIG. 9 illustrates graph 900 of selected sensor data from graph 800 corresponding to a plurality of time instances. FIG. 9 also illustrates graph 902 of a plurality of derivative signals generated based on the sensor data from graph 900 and FIG. 8 for in-situ control of the first plasma-based process, according to some embodiments. As illustrated in FIG. 9, the generated plurality of derivative signals in connection with an etch process may include a single negative peak derivative signal, such as negative peak derivative signal 904. The negative peak derivative signal 904 is at time T1, which is after time TO when the plasma for the etch process is initiated.

In some embodiments, the negative peak derivative signal 904 may be detected by controller 116 as a derivative signal that corresponds to a time instance of the plurality of time instances when the carbon substrate (e.g., a planar top surface of the substrate) is cleared as a result of the etch process. In another embodiment, controller 116 may determine the endpoint for the etch process based on the time instance of the plurality of time instances. In some aspects, the endpoint for the etch process may be the time instance of the plurality of time instances delayed by a predetermined threshold time duration.

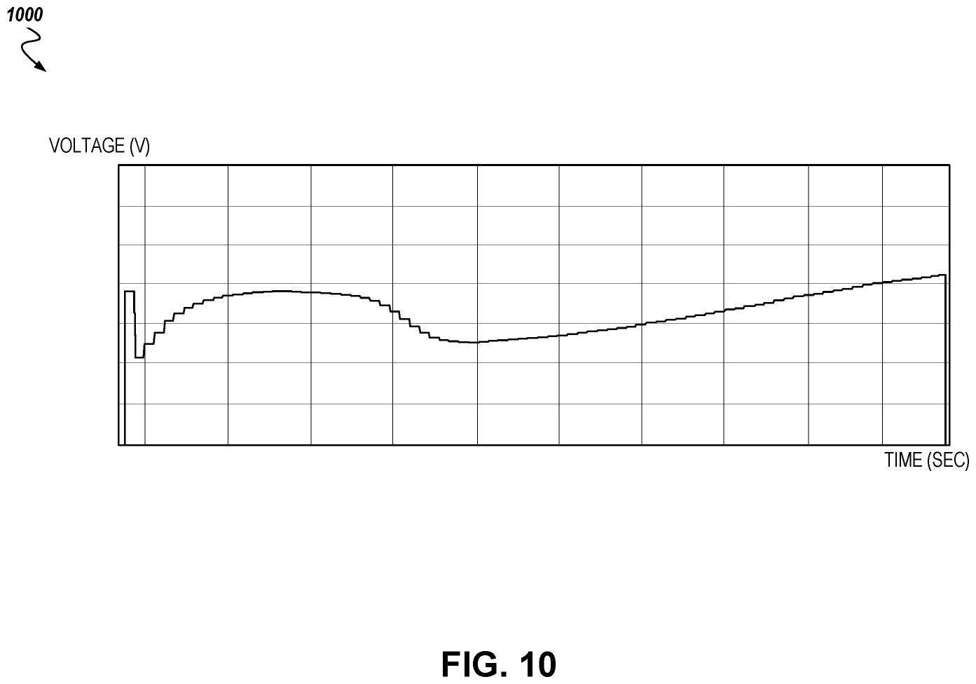

FIG. 10 illustrates graph 1000 of collected sensor data including voltage associated with an RF signal used for a third plasma-based etch process, according to some embodiments. More specifically, graph 1000 is associated with a third plasma-based etch process which may be a CO₂ etch performed on a clean carbon substrate in a vacuum chamber with the presence of carbon inside the chamber.

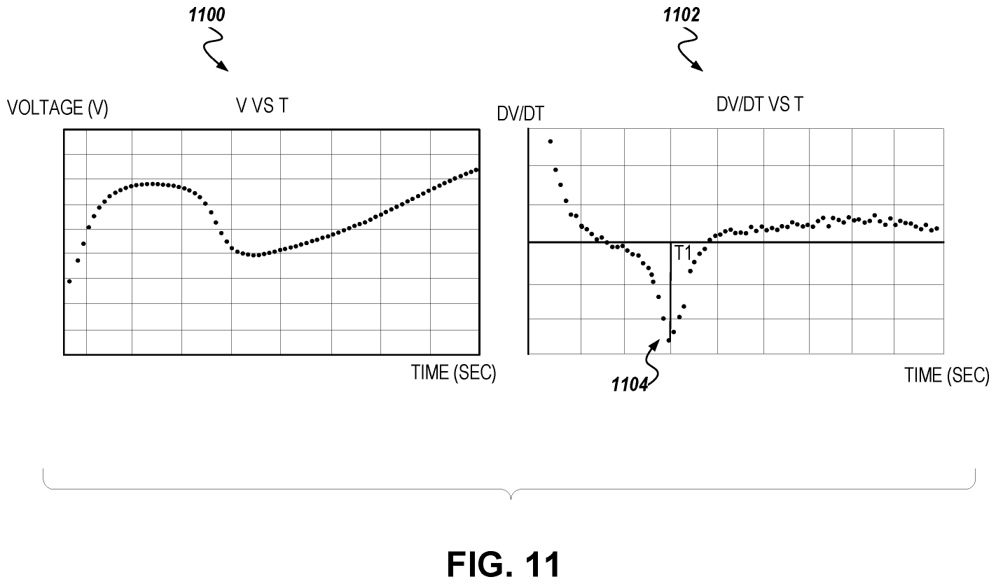

FIG. 11 illustrates graph 1100 of selected sensor data from graph 1000 corresponding to a plurality of time instances. FIG. 11 also illustrates graph 1102 of a plurality of derivative signals generated based on the sensor data from graph 1100 and FIG. 10 for in-situ control of the first plasma-based process, according to some embodiments. As illustrated in FIG. 11, the generated plurality of derivative signals in connection with an etch process may include a single negative peak derivative signal, such as a negative peak derivative signal 1104. The negative peak derivative signal 1104 is at time T1, which is after the time when the plasma for the etch process is initiated.

In some embodiments, the negative peak derivative signal 1104 may be detected by controller 116 as a derivative signal that corresponds to a time instance of the plurality of time instances when the vacuum chamber is cleared of the presence of carbon. FIG. 11 does not illustrate a second negative peak derivative signal since a clean substrate has been used for the etching process.

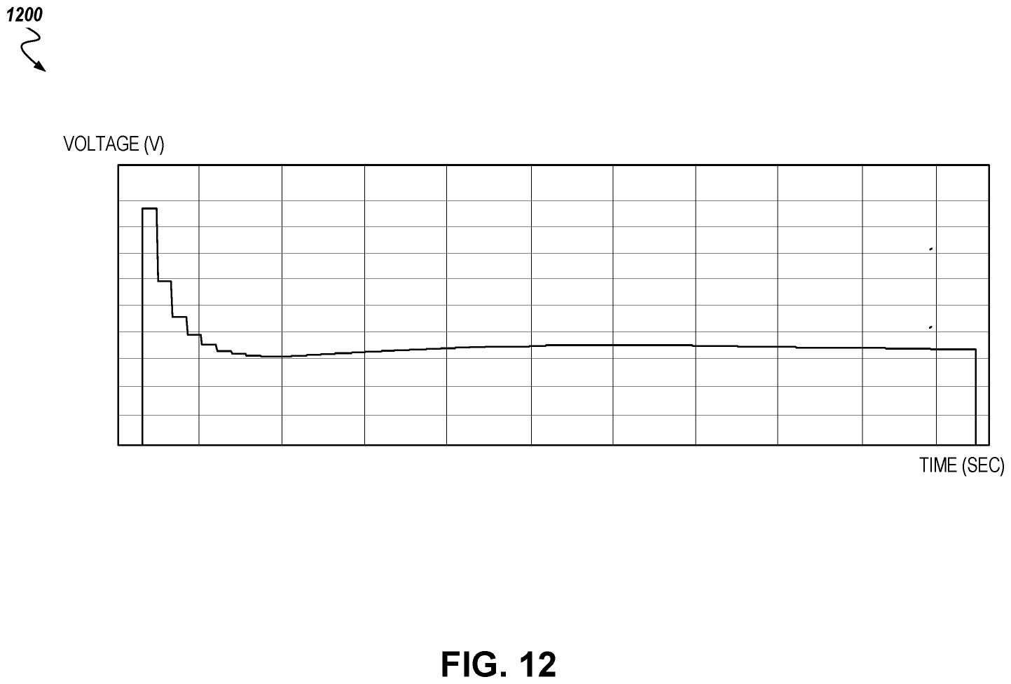

FIG. 12 illustrates graph 1200 of collected sensor data including voltage associated with an RF signal used for a fourth plasma-based etch process, according to some embodiments. More specifically, graph 1200 is associated with a fourth plasma-based etch process which may be a CO₂ etch performed on a clean carbon substrate in a vacuum chamber without the presence of carbon inside the chamber.

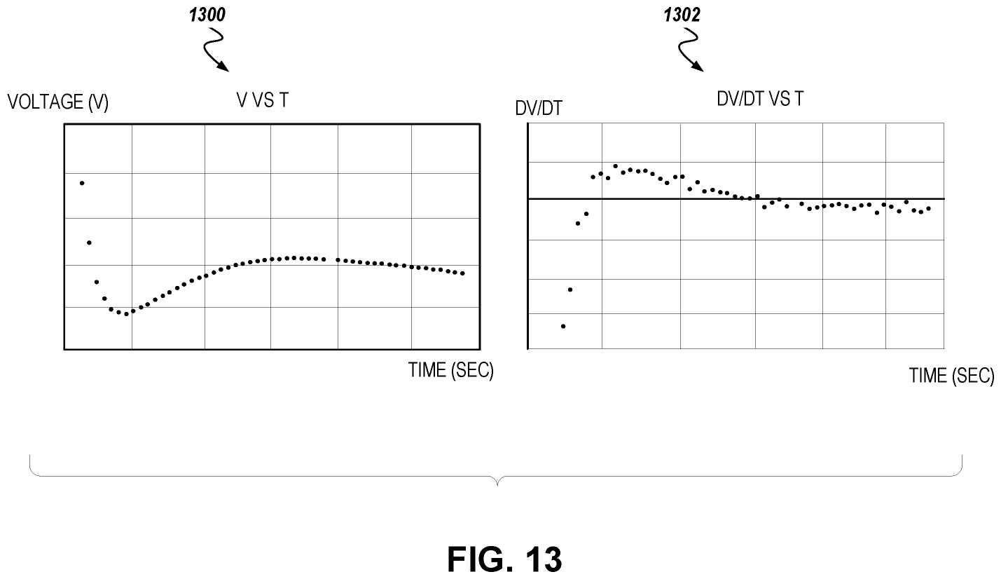

FIG. 13 illustrates a graph 1300 of selected sensor data from graph 1200 corresponding to a plurality of time instances. FIG. 13 also illustrates graph 1302 of a plurality of derivative signals generated based on the sensor data from graph 1300 and FIG. 12 for in-situ control of the first plasma-based process, according to some embodiments. As illustrated in FIG. 13, the generated plurality of derivative signals in connection with an etch process does not include any negative peak derivative signals since the etch process is performed in a carbon-free vacuum chamber on a clean substrate (e.g., a substrate without a top carbon layer).

FIG. 14 illustrates graph 1400 of collected sensor data including impedance associated with an RF signal, and a graph 1406 of a plurality of derivative signals generated based on the sensor data for in-situ control of a multi-step plasma-based process, according to some embodiments. More specifically, the multi-step process includes a deposition process (e.g., carbon deposition process) followed by an etch process (e.g., hydrogen etch process). Graph 1400 includes sensor data (e.g., impedance data) 1402 collected at a first plurality of time instances during the deposition process. Graph 1400 also includes sensor data 1404 collected at a second plurality of time instances during the etch process.

Graph 1406 includes a plurality of derivative signals generated based on the sensor data from graph 1400. As illustrated in FIG. 14, the generated plurality of derivative signals of graph 1406 in connection with the deposition process includes a first positive peak derivative signal 1408. The first positive peak derivative signal 1408 is at time T1 (after time TO when the plasma for the deposition process is initiated). In some embodiments, the first positive peak derivative signal 1408 corresponds to a time instance (e.g., T1) of the first plurality of time instances when a structured top surface of the substrate is filled. Controller 116 may use the first positive peak derivative signal 1408 to determine a first endpoint for the deposition process based on the time instance of the first plurality of time instances.

The generated plurality of derivative signals of graph 1406 in connection with the etch process includes a second positive peak derivative signal 1410. The second positive peak derivative signal 1410 is at time T2 (after time TO when the plasma for the deposition process is initiated). In some embodiments, the second positive peak derivative signal 1410 corresponds to a time instance (e.g., T2) of the second plurality of time instances when a planar top surface of the substrate is cleared. Controller 116 may use the second positive peak derivative signal 1410 to determine a second endpoint for the etch process based on the time instance of the second plurality of time instances. In this regard, the disclosed techniques may be used for in-situ endpoint detection and process control of multi-step plasma-based processes.

Even though FIG. 14 and the corresponding description relate to determining a single deposition process endpoint and a single etch process endpoint the disclosure is not limited in this regard. In some embodiments, the disclosed techniques may be used for endpoint detection of multiple deposition processes and multiple etch processes within deposition and etch cycling processes.

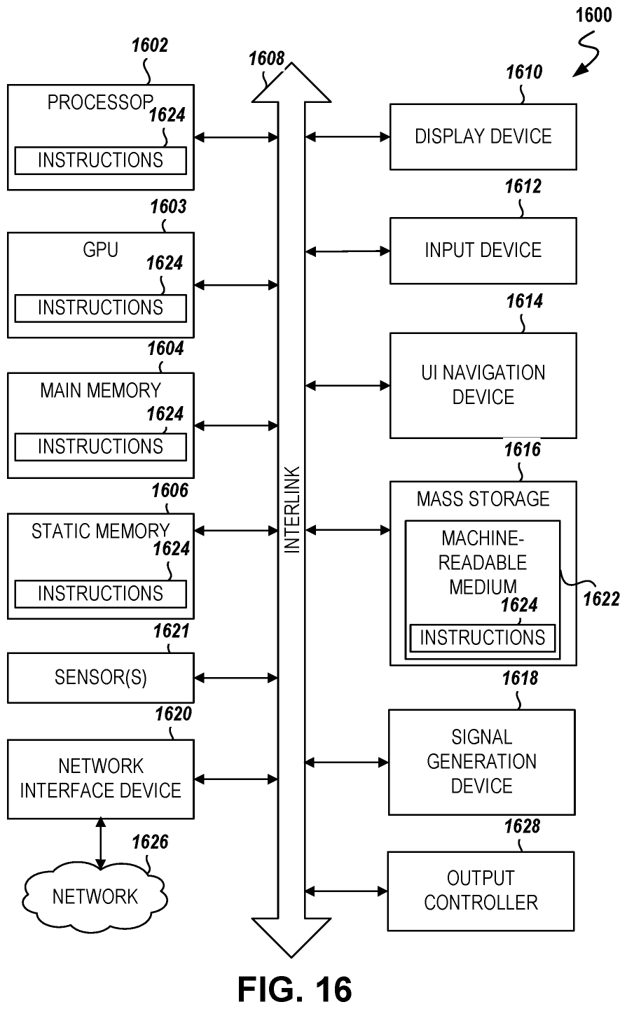

FIG. 15 is a flowchart of a method 1500 for processing a substrate using a plasma-based process, according to some example embodiments. Method 1500 includes operations 1502, 1504, 1506, and 1508, which may be performed by a controller (e.g., controller 116 of FIG. 1) or a processor (e.g., processor 1602 of FIG. 16). Referring to FIG. 15, at operation 1502, an RF signal is applied between a first electrode (e.g., an upper electrode) and a second electrode (e.g., a lower electrode) of a vacuum chamber to generate plasma for a plasma-based process. For example, an RF generator generates an RF signal applied between the upper electrode 104 and the lower electrode 108 of the vacuum chamber 100. Process gas is supplied by the gas source 122 into the processing zone 130. The RF signal causes the generation of plasma using the process gas within the processing zone 130.

At operation 1504, a plurality of sensor signals is received during the plasma-based process. For example, controller 116 receives a plurality of sensor signals from sensor 128. The plurality of sensor signals may be indicative of at least one signal characteristic of the RF signal at a corresponding plurality of time instances. For example and as described in connection with FIG. 3-FIG. 14, the plurality of sensor signals may include signals indicative of voltage, current, phase, delivered power, or impedance.

At operation 1506, an endpoint for the plasma-based process is determined based on the plurality of sensor signals. For example and in FIG. 5, derivative signals illustrated by graph 508 are generated using the plurality of sensor signals (indicative of impedance) collected at a corresponding plurality of time instances as reflected by graph 502. The controller 116 may detect a positive peak derivative signal (e.g., at a time instance T1 in graph 508) from the plurality of derivative signals. The positive peak derivative signal may correspond to a time instance (e.g., T1) of the plurality of time instances when a structured top surface of the substrate is filled with a carbon plug during the deposition process (e.g., as illustrated in FIG. 3). Controller 116 may further determine the endpoint for the deposition process based on the time instance (e.g., T1) of the plurality of time instances. For example, the endpoint for the deposition process may be determined as the time instance (e.g., T1) of the plurality of time instances delayed by a predetermined threshold time duration. At operation 1508, the plasma-based process may be terminated based on the endpoint.

FIG. 16 is a block diagram illustrating an example of a machine 1600 upon or by which one or more example process embodiments described herein may be implemented or controlled. In alternative embodiments, the machine 1600 may operate as a standalone device or may be connected (e.g., networked) to other machines. In a networked deployment, the machine 1600 may operate in the capacity of a server machine, a client machine, or both in server-client network environments. In an example, the machine 1600 may act as a peer machine in a peer-to-peer (P2P) (or other distributed) network environment. Further, while only a single machine 1600 is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, several components, or mechanisms. Circuitry is a collection of circuits implemented in tangible entities that include hardware (e.g., simple circuits, gates, logic). Circuitry membership may be flexible over time and underlying hardware variability. Circuitries include members that may, alone or in combination, perform specified operations when operating. In an example, the hardware of the circuitry may be immutably designed to carry out a specific operation (e.g., hardwired). In an example, the hardware of the circuitry may include variably connected physical components (e.g., execution units, transistors, simple circuits) including a computer-readable medium physically modified (e.g., magnetically, electrically, by the moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In some aspects, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 1600 may include a hardware processor 1602 (e.g., a central processing unit (CPU), a hardware processor core, or any combination thereof), a graphics processing unit (GPU) 1603, a main memory 1604, and a static memory 1606, some or all of which may communicate with each other via an interlink (e.g., bus) 1608. The machine 1600 may further include a display device 1610, an alphanumeric input device 1612 (e.g., a keyboard), and a user interface (UI) navigation device 1614 (e.g., a mouse). In an example, the display device 1610, alphanumeric input device 1612, and UI navigation device 1614 may be a touch screen display. The machine 1600 may additionally include a mass storage device (e.g., drive unit) 1616, a signal generation device 1618 (e.g., a speaker), a network interface device 1620, and one or more sensors 1621, such as a Global Positioning System (GPS) sensor, compass, accelerometer, or another sensor. The machine 1600 may include an output controller 1628, such as a serial (e.g., universal serial bus (USB)), parallel, or other wired or wireless (e.g., infrared (IR), near field communication (NFC)) connection to communicate with or control one or more peripheral devices (e.g., a printer, card reader).

In an example embodiment, the hardware processor 1602 may perform the functionalities of the controller 116 discussed hereinabove, in connection with at least FIG. 1-FIG. 15.

The mass storage device 1616 may include a machine-readable medium 1622 on which is stored one or more sets of data structures or instructions 1624 (e.g., software) embodying or utilized by any one or more of the techniques or functions described herein. The instructions 1624 may also reside, completely or at least partially, within the main memory 1604, within the static memory 1606, within the hardware processor 1602, or within the GPU 1603 during execution thereof by the machine 1600. In an example, one or any combination of the hardware processor 1602, the GPU 1603, the main memory 1604, the static memory 1606, or the mass storage device 1616 may constitute machine-readable media.

While the machine-readable medium 1622 is illustrated as a single medium, the term “machine-readable medium” may include a single medium or multiple media, (e.g., a centralized or distributed database, and/or associated caches and servers) configured to store the one or more instructions 1624.

The term “machine-readable medium” may include any medium that is capable of storing, encoding, or carrying instructions 1624 for execution by the machine 1600 and that causes the machine 1600 to perform any one or more of the techniques of the present disclosure, or that is capable of storing, encoding, or carrying data structures used by or associated with such instructions 1624. Non-limiting machine-readable medium examples may include solid-state memories and optical and magnetic media. In an example, a massed machine-readable medium comprises a machine-readable medium 1622 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 1624 may further be transmitted or received over a communications network 1626 using a transmission medium via the network interface device 1620.

Implementation of the preceding techniques may be accomplished through any number of specifications, configurations, or example deployments of hardware and software. It should be understood that the functional units or capabilities described in this specification may have been referred to or labeled as components or modules, to more particularly emphasize their implementation independence. Such components may be embodied by any number of software or hardware forms. For example, a component or module may be implemented as a hardware circuit comprising custom very-large-scale integration (VLSI) circuits or gate arrays, off-the-shelf semiconductors such as logic chips, transistors, or other discrete components. A component or module may also be implemented in programmable hardware devices such as field-programmable gate arrays, programmable array logic, programmable logic devices, or the like. Components or modules may also be implemented in software for execution by various types of processors. An identified component or module of executable code may, for instance, comprise one or more physical or logical blocks of computer instructions, which may, for instance, be organized as an object, procedure, or function. Nevertheless, the executables of an identified component or module need not be physically located together but may comprise disparate instructions stored in different locations which, when joined logically together, comprise the component or module and achieve the stated purpose for the component or module.

Indeed, a component or module of executable code may be a single instruction, or many instructions, and may even be distributed over several different code segments, among different programs, and across several memory devices or processing systems. In particular, some aspects of the described process (such as code rewriting and code analysis) may take place on a different processing system (e.g., in a computer in a data center), than that in which the code is deployed (e.g., in a computer embedded in a sensor or robot). Similarly, operational data may be identified and illustrated herein within components or modules and may be embodied in any suitable form and organized within any suitable type of data structure. The operational data may be collected as a single data set or may be distributed over different locations including over different storage devices, and may exist, at least partially, merely as electronic signals on a system or network. The components or modules may be passive or active, including agents operable to perform desired functions.

### Additional Notes and Examples

Example 1 is an apparatus comprising: a vacuum chamber comprising a processing zone, the vacuum chamber configured to receive process gas for a plasma-based process of a substrate; a radio frequency (RF) generator configured to provide an RF signal between a first electrode and a second electrode of the vacuum chamber to generate plasma for the plasma-based process, the plasma generated within the processing zone using the process gas; a sensor coupled to the RF generator and configured to sense at least one signal characteristic of the RF signal; and a controller coupled to the sensor and configured to: retrieve, during the plasma-based process, a plurality of signals from the sensor, the plurality of signals indicative of the at least one signal characteristic of the RF signal at a corresponding plurality of time instances; generate a plurality of derivative signals based on the plurality of signals; and determine an endpoint for the plasma-based process based on the plurality of derivative signals.

In Example 2, the subject matter of Example 1 includes, wherein the plasma-based process is a deposition process, and the controller is further configured to detect a positive peak derivative signal from the plurality of derivative signals, the positive peak derivative signal corresponding to a time instance of the plurality of time instances when a structured top surface of the substrate is filled with a carbon plug during the deposition process.

In Example 3, the subject matter of Example 2 includes, wherein the controller is further configured to determine the endpoint for the deposition process based on the time instance of the plurality of time instances.

In Example 4, the subject matter of Example 3 includes, wherein the endpoint for the deposition process is the time instance of the plurality of time instances delayed by a predetermined threshold time duration.

In Example 5, the subject matter of Example 4 includes, wherein the predetermined threshold time duration corresponds to a predetermined depth of the carbon plug.

In Example 6, the subject matter of Examples 2-5 includes, wherein the controller is further configured to determine a peak width associated with the positive peak derivative signal; determine a non-uniformity estimate for the substrate at the time instance of the plurality of time instances based on the peak width; and adjust a flow rate of the process gas during the plasma-based process based on the non-uniformity estimate.

In Example 7, the subject matter of Examples 1-6 includes, wherein the plasma-based process is an etch process, and the controller is further configured to detect a negative peak derivative signal from the plurality of derivative signals, the negative peak derivative signal corresponding to a time instance of the plurality of time instances when a planar top surface of the substrate is cleared during the etch process.

In Example 8, the subject matter of Example 7 includes, wherein the controller is further configured to determine the endpoint for the etch process based on the time instance of the plurality of time instances, wherein the endpoint for the etch process is the time instance of the plurality of time instances delayed by a predetermined threshold time duration.

In Example 9, the subject matter of Examples 1-8 includes, wherein the plasma-based process is a multi-step process comprising a deposition process followed by an etch process, and the controller is further configured to detect during the deposition process, a first positive peak derivative signal from the plurality of derivative signals, the positive peak derivative signal corresponding to a first time instance of the plurality of time instances when a structured top surface of the substrate is filled; and determine a first endpoint for the deposition process based on the first time instance of the plurality of time instances.

In Example 10, the subject matter of Example 9 includes, wherein the controller is further configured to detect during the etch process, a second positive peak derivative signal from the plurality of derivative signals, the second positive peak derivative signal corresponding to a second time instance of the plurality of time instances when a planar top surface of the substrate is cleared; and determine a second endpoint for the etch process based on the second time instance of the plurality of time instances.

In Example 11, the subject matter of Examples 1-10 includes, wherein the sensor is a voltage-current sensor, and wherein the at least one signal characteristic of the RF signal comprises at least one of voltage associated with the RF signal; and impedance associated with the RF signal.

In Example 12, the subject matter of Examples 1-11 includes, wherein the first electrode is an upper electrode and the second electrode is a lower electrode of the vacuum chamber, and wherein the controller is further configured to terminate the plasma-based process based on the endpoint.

Example 13 is a method for processing a substrate using a plasma-based process, the method comprising: applying a radio frequency (RF) signal between a first electrode and a second electrode of a vacuum chamber to generate plasma for the plasma-based process; receiving during the plasma-based process, a plurality of sensor signals, the plurality of sensor signals indicative of at least one signal characteristic of the RF signal at a corresponding plurality of time instances; determining an endpoint for the plasma-based process based on the plurality of sensor signals; and terminating the plasma-based process based on the endpoint.

In Example 14, the subject matter of Example 13 includes, generating a plurality of derivative signals based on the plurality of sensor signals; and determining the endpoint based on the plurality of derivative signals.

In Example 15, the subject matter of Examples 13-14 includes, wherein the plasma-based process is a deposition process, and the method further comprises: detecting a positive peak derivative signal from the plurality of derivative signals, the positive peak derivative signal corresponding to a time instance of the plurality of time instances when a structured top surface of the substrate is filled with a carbon plug during the deposition process.

In Example 16, the subject matter of Example 15 includes, determining the endpoint for the deposition process based on the time instance of the plurality of time instances, wherein the endpoint for the deposition process is the time instance of the plurality of time instances delayed by a predetermined threshold time duration.

In Example 17, the subject matter of Example 16 includes, wherein the predetermined threshold time duration corresponds to a predetermined depth of the carbon plug.

In Example 18, the subject matter of Examples 15-17 includes, determining a peak width associated with the positive peak derivative signal; determining a non-uniformity estimate for the substrate at the time instance of the plurality of time instances based on the peak width; and adjusting based on the non-uniformity estimate, a flow rate of a process gas used for generating the plasma during the plasma-based process.

In Example 19, the subject matter of Examples 13-18 includes, wherein the plasma-based process is an etch process, and the method further comprises: detecting a negative peak derivative signal from the plurality of derivative signals, the negative peak derivative signal corresponding to a time instance of the plurality of time instances when a planar top surface of the substrate is cleared during the etch process.

In Example 20, the subject matter of Example 19 includes, determining the endpoint for the etch process based on the time instance of the plurality of time instances, wherein the endpoint for the etch process is the time instance of the plurality of time instances delayed by a predetermined threshold time duration.

In Example 21, the subject matter of Examples 13-20 includes, wherein the plasma-based process is a multi-step process comprising a deposition process followed by an etch process, and the method further comprising: detecting during the deposition process, a first positive peak derivative signal from the plurality of derivative signals, the positive peak derivative signal corresponding to a first time instance of the plurality of time instances when a structured top surface of the substrate is filled; and determining a first endpoint for the deposition process based on the first time instance of the plurality of time instances.

In Example 22, the subject matter of Example 21 includes, detecting during the etch process, a second positive peak derivative signal from the plurality of derivative signals, the second positive peak derivative signal corresponding to a second time instance of the plurality of time instances when a planar top surface of the substrate is cleared; and determining a second endpoint for the etch process based on the second time instance of the plurality of time instances.

Example 23 is a non-transitory machine-readable storage medium including instructions that, when executed by a machine, cause the machine to perform operations for processing a substrate, the operations comprising: applying a radio frequency (RF) signal between a first electrode and a second electrode of a vacuum chamber to generate plasma for a plasma-based process; receiving during the plasma-based process, a plurality of sensor signals, the plurality of sensor signals indicative of at least one signal characteristic of the RF signal at a corresponding plurality of time instances; generating a plurality of derivative signals based on the plurality of sensor signals; determining an endpoint for the plasma-based process based on the plurality of derivative signals; and terminating the plasma-based process based on the endpoint.

In Example 24, the subject matter of Example 23 includes, wherein the plasma-based process is a deposition process, the operations further comprising: detecting a positive peak derivative signal from the plurality of derivative signals, the positive peak derivative signal corresponding to a time instance of the plurality of time instances when a structured top surface of the substrate is filled with a carbon plug during the deposition process.

In Example 25, the subject matter of Example 24 includes, the operations further comprising: determining the endpoint for the deposition process based on the time instance of the plurality of time instances, wherein the endpoint for the deposition process is the time instance of the plurality of time instances delayed by a predetermined threshold time duration, wherein the predetermined threshold time duration corresponds to a predetermined depth of the carbon plug.

In Example 26, the subject matter of Examples 23-25 includes, wherein the plasma-based process is an etch process, and the operations further comprise: detecting a negative peak derivative signal from the plurality of derivative signals, the negative peak derivative signal corresponding to a time instance of the plurality of time instances when a planar top surface of the substrate is cleared during the etch process.

In Example 27, the subject matter of Example 26 includes, the operations further comprising: determining the endpoint for the etch process based on the time instance of the plurality of time instances, wherein the endpoint for the etch process is the time instance of the plurality of time instances delayed by a predetermined threshold time duration.

Example 28 is at least one machine-readable medium including instructions that, when executed by processing circuitry, cause the processing circuitry to perform operations to implement any of Examples 1-27.

Example 29 is an apparatus comprising means to implement any of Examples 1-27.

Example 30 is a system to implement any of Examples 1-27.

Example 31 is a method to implement any of Examples 1-27.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components for example configurations may be implemented as a combined structure or component. Similarly, structures and functionality presented as a single component may be implemented as separate components. These and other variations, modifications, additions, and improvements fall within the scope of the subject matter herein.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

The claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within the scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

What is claimed is:

1. An apparatus comprising:
a vacuum chamber comprising a processing zone, the vacuum chamber configured to receive process gas for a plasma-based process of a substrate;
a radio frequency (RF) generator configured to provide an RF signal between a first electrode and a second electrode of the vacuum chamber to generate plasma for the plasma-based process, the plasma generated within the processing zone using the process gas;
a sensor coupled to the RF generator and configured to sense at least one signal characteristic of the RF signal; and
a controller coupled to the sensor and configured to:
retrieve, during the plasma-based process, a plurality of signals from the sensor, the plurality of signals indicative of the at least one signal characteristic of the RF signal at a corresponding plurality of time instances;
generate a plurality of derivative signals based on the plurality of signals; and
determine an endpoint for the plasma-based process based on the plurality of derivative signals.

2. The apparatus of claim 1, wherein the plasma-based process is a deposition process, and the controller is further configured to:
detect a positive peak derivative signal from the plurality of derivative signals, the positive peak derivative signal corresponding to a time instance of the plurality of time instances when a structured top surface of the substrate is filled with a carbon plug during the deposition process.

3. The apparatus of claim 2, wherein the controller is further configured to:
determine the endpoint for the deposition process based on the time instance of the plurality of time instances.

4. The apparatus of claim 3, wherein the endpoint for the deposition process is the time instance of the plurality of time instances delayed by a predetermined threshold time duration.

5. The apparatus of claim 4, wherein the predetermined threshold time duration corresponds to a predetermined depth of the carbon plug.

6. The apparatus of claim 2, wherein the controller is further configured to:
determine a peak width associated with the positive peak derivative signal;
determine a non-uniformity estimate for the substrate at the time instance of the plurality of time instances based on the peak width; and
adjust a flow rate of the process gas during the plasma-based process based on the non-uniformity estimate.

7. The apparatus of claim 1, wherein the plasma-based process is an etch process, and the controller is further configured to:
detect a negative peak derivative signal from the plurality of derivative signals, the negative peak derivative signal corresponding to a time instance of the plurality of time instances when a planar top surface of the substrate is cleared during the etch process.

8. The apparatus of claim 7, wherein the controller is further configured to:
determine the endpoint for the etch process based on the time instance of the plurality of time instances, wherein the endpoint for the etch process is the time instance of the plurality of time instances delayed by a predetermined threshold time duration.

9. The apparatus of claim 1, wherein the plasma-based process is a multi-step process comprising a deposition process followed by an etch process, and the controller is further configured to:
detect during the deposition process, a first positive peak derivative signal from the plurality of derivative signals, the positive peak derivative signal corresponding to a first time instance of the plurality of time instances when a structured top surface of the substrate is filled; and
determine a first endpoint for the deposition process based on the first time instance of the plurality of time instances.

10. The apparatus of claim 9, wherein the controller is further configured to:
detect during the etch process, a second positive peak derivative signal from the plurality of derivative signals, the second positive peak derivative signal corresponding to a second time instance of the plurality of time instances when a planar top surface of the substrate is cleared; and
determine a second endpoint for the etch process based on the second time instance of the plurality of time instances.

11. The apparatus of claim 1, wherein the sensor is a voltage-current sensor, and wherein the at least one signal characteristic of the RF signal comprises at least one of:
voltage associated with the RF signal; and
impedance associated with the RF signal.

12. The apparatus of claim 1, wherein the first electrode is an upper electrode and the second electrode is a lower electrode of the vacuum chamber, and wherein the controller is further configured to:
terminate the plasma-based process based on the endpoint.

13. A method for processing a substrate using a plasma-based process, the method comprising:
applying a radio frequency (RF) signal between a first electrode and a second electrode of a vacuum chamber to generate plasma for the plasma-based process;
receiving during the plasma-based process, a plurality of sensor signals, the plurality of sensor signals indicative of at least one signal characteristic of the RF signal at a corresponding plurality of time instances;
determining an endpoint for the plasma-based process based on the plurality of sensor signals; and
terminating the plasma-based process based on the endpoint.

14. The method of claim 13, further comprising:
generating a plurality of derivative signals based on the plurality of sensor signals; and
determining the endpoint based on the plurality of derivative signals.

15. The method of claim 14, wherein the plasma-based process is a deposition process, and the method further comprises:
detecting a positive peak derivative signal from the plurality of derivative signals, the positive peak derivative signal corresponding to a time instance of the plurality of time instances when a structured top surface of the substrate is filled with a carbon plug during the deposition process.

16. The method of claim 15, further comprising:
determining the endpoint for the deposition process based on the time instance of the plurality of time instances, wherein the endpoint for the deposition process is the time instance of the plurality of time instances delayed by a predetermined threshold time duration.

17. The method of claim 16, wherein the predetermined threshold time duration corresponds to a predetermined depth of the carbon plug.

18. The method of claim 15, further comprising:
determining a peak width associated with the positive peak derivative signal;
determining a non-uniformity estimate for the substrate at the time instance of the plurality of time instances based on the peak width; and
adjusting based on the non-uniformity estimate, a flow rate of a process gas used for generating the plasma during the plasma-based process.

19. The method of claim 14, wherein the plasma-based process is an etch process, and the method further comprises:
detecting a negative peak derivative signal from the plurality of derivative signals, the negative peak derivative signal corresponding to a time instance of the plurality of time instances when a planar top surface of the substrate is cleared during the etch process.

20. The method of claim 19, further comprising:
determining the endpoint for the etch process based on the time instance of the plurality of time instances, wherein the endpoint for the etch process is the time instance of the plurality of time instances delayed by a predetermined threshold time duration.

21. The method of claim 14, wherein the plasma-based process is a multi-step process comprising a deposition process followed by an etch process, and the method further comprising:
detecting during the deposition process, a first positive peak derivative signal from the plurality of derivative signals, the positive peak derivative signal corresponding to a first time instance of the plurality of time instances when a structured top surface of the substrate is filled; and
determining a first endpoint for the deposition process based on the first time instance of the plurality of time instances.

22. The method of claim 21, further comprising:
detecting during the etch process, a second positive peak derivative signal from the plurality of derivative signals, the second positive peak derivative signal corresponding to a second time instance of the plurality of time instances when a planar top surface of the substrate is cleared; and
determining a second endpoint for the etch process based on the second time instance of the plurality of time instances.

23. A machine-readable storage medium including instructions that, when executed by a machine, cause the machine to perform operations for processing a substrate, the operations comprising:
applying a radio frequency (RF) signal between a first electrode and a second electrode of a vacuum chamber to generate plasma for a plasma-based process;
receiving during the plasma-based process, a plurality of sensor signals, the plurality of sensor signals indicative of at least one signal characteristic of the RF signal at a corresponding plurality of time instances;
generating a plurality of derivative signals based on the plurality of sensor signals;
determining an endpoint for the plasma-based process based on the plurality of derivative signals; and
terminating the plasma-based process based on the endpoint.

24. The machine-readable storage medium of claim 23, wherein the plasma-based process is a deposition process, the operations further comprising:
detecting a positive peak derivative signal from the plurality of derivative signals, the positive peak derivative signal corresponding to a time instance of the plurality of time instances when a structured top surface of the substrate is filled with a carbon plug during the deposition process.

25. The machine-readable storage medium of claim 24, the operations further comprising:
determining the endpoint for the deposition process based on the time instance of the plurality of time instances, wherein the endpoint for the deposition process is the time instance of the plurality of time instances delayed by a predetermined threshold time duration, wherein the predetermined threshold time duration corresponds to a predetermined depth of the carbon plug.

26. The machine-readable storage medium of claim 23, wherein the plasma-based process is an etch process, and the operations further comprise:
detecting a negative peak derivative signal from the plurality of derivative signals, the negative peak derivative signal corresponding to a time instance of the plurality of time instances when a planar top surface of the substrate is cleared during the etch process.

27. The machine-readable storage medium of claim 26, the operations further comprising:
determining the endpoint for the etch process based on the time instance of the plurality of time instances, wherein the endpoint for the etch process is the time instance of the plurality of time instances delayed by a predetermined threshold time duration.
